(19) United States
(12) Patent Application Publication
(10) Pub. No.: US 2014/0352778 A1
(43) Pub. Date: Dec. 4, 2014

(54) SOLAR CELL PASTES FOR LOW RESISTANCE CONTACTS

(71) Applicant: Heraeus Precious Metals North America Conshohocken LLC, West Conshohocken, PA (US)

(72) Inventors: Yi Yang, San Diego, CA (US); Srinvasan Sridharan, Strongsville, OH (US); Umesh Kumar, Calrsbad, CA (US); Aziz Shaikh, San Diego, CA (US)

(21) Appl. No.: 14/365,780

(22) PCT Filed: Dec. 21, 2012
(86) PCT No.: PCT/US2012/071119

§ 371 Date: Jun. 16, 2014

Related U.S. Application Data
(60) Provisional application No. 61/579,159, filed on Dec. 22, 2011.

(51) Int. Cl. H01B 1/16; H01L 31/18; H01L 31/0224

(52) U.S. Cl. CPC H01B 1/16; H01L 31/022425; H01L 31/1884
USPC 136/256; 438/98; 252/512; 252/513; 252/514

(57) ABSTRACT

Paste compositions, methods of making a paste composition, solar cells, and methods of making a solar cell contact are disclosed. The paste composition can include a conductive metal component, a glass component, and a vehicle. The glass component can include SiO₂ at about 3 mole % or more and about 65 mole % or less of the glass component and one or more transition metal oxides at about 0.1 mole % or more and about 25 mole % or less of the glass component. The metal of the transition metal oxide is selected from the group consisting of Mn, Fe, Co, Ni, Cu, Ti, V, Cr, W, Nb, Ta, Hf, Mo, Zr, Rh, Ru, Pd, and Pt.

### TECHNICAL FIELD

The subject disclosure generally relates to paste compositions, methods of making a paste composition, solar cells, and methods of making a solar cell contact.

### BACKGROUND

Solar cells are generally made of semiconductor materials, such as silicon (Si), which convert sunlight into useful electrical energy. Solar cells are typically made of thin wafers of Si in which the required PN junction is formed by diffusing phosphorus (P) from a suitable phosphorus source into a P-type Si wafer. The side of silicon wafer on which sunlight is incident is in general coated with an anti-reflective coating (ARC) to prevent reflective loss of incoming sunlight, and thus to increase the efficiency of the solar cell. A two dimensional electrode grid pattern known as a front contact makes a connection to the N-side of silicon, and a coating of aluminum (Al) on the other side (back contact) makes connection to the P-side of the silicon. These contacts are the electrical outlets from the PN junction to the outside load.

Front contacts of silicon solar cells are typically formed by screen-printing a thick film paste. Typically, the paste contains approximately fine silver particles, glass and organics. After screen-printing, the wafer and paste are fired in air, typically at furnace set temperatures of about 650-1000° C. During the firing, glass softens, melts, and reacts with the anti-reflective coating, etches the silicon surface, and facilitates the formation of intimate silicon-silver contact. Silver deposits on silicon as islands. The shape, size, and number of silicon-silver islands determine the efficiency of electron transfer from silicon to the outside circuit.

### SUMMARY

The following presents a simplified summary of the invention in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later

An aspect of the invention is a paste composition comprising: (a) from about 50 wt % to about 95 wt % of a conductive metal component, and (b) from about 0.5 wt % to about 15 wt % of a glass component, the glass component comprising at least one glass composition having a glass transition temperature (Tg) less than about 600° C.

Another aspect of the invention is a paste composition comprising: (a) from about 50 wt % to about 95 wt % of a conductive metal component and (b) from about 0.5 wt % to about 15 wt % of a glass component, the glass component comprising at least a first glass composition has softening point less than about 700° C.

An embodiment of the invention is a paste composition comprising: (a) from about 50 wt % to about 95 wt % of a conductive metal component, (b) from about 0.5 wt % to about 15 wt % of a glass component, the glass component comprising at least a first glass composition, comprising, (i) from about 55 to about 80 mol % PbO, (ii) from about 4 to about 13 mol % SiO₂, (iii) from about 11 to about 22 mol % Al₂O₃, (iv) from about 3 to about 10 mol % MnO, (v) from about 0.5 to about 5 mol % M₂O₅ wherein M is selected from the group consisting of P, Ta, As, Sb, V, Nb, and combinations thereof, and (vi) from about 0.1 to about 3 mol % MO₂, wherein M is selected from the group consisting of Ti, Zr, and Hf.

An embodiment of the invention is a paste composition comprising: (a) from about 50 wt % to about 95 wt % of a conductive metal component, (b) from about 0.5 wt % to about 15 wt % of a glass component, the glass component comprising at least a first glass composition, comprising (i) from about 17 to about 51, preferably from about 21.1 to about 43.9 mol % PbO, (ii) from about 14 to about 47, preferably from about 15.6 to about 39.8 mol % ZnO, (iii) from about 24.3 to about 32.1, preferably from about 25.7 to about 31.1 mol % SiO₂, (iv) from about 6.2 to about 13.1, preferably from about 6.9 to about 12.2 mol % Al₂O₃, and (v) from about 0.2 to about 4.1, preferably from about 0.5 to about 3.7 mol % M₂O₅ wherein M is selected from the group consisting of P, Ta, V, Sb, Nb and combinations thereof.

Another embodiment of the invention is a paste composition comprising: (a) from about 50 wt % to about 95 wt % of a conductive metal component, (b) from about 0.5 wt % to about 15 wt % of a glass component, the glass component comprising at least a first glass composition, comprising (i) from about 5.2 to about 17.1, preferably from about 7.2 to about 13.4 mol %, ZnO, (ii) from about 37.8 to about 71.2, preferably from about 46.2 to about 65.9 mol % SiO₂, (iii) from about 7.7 to about 15.9, preferably 8.2 to about 15.2 mol % B₂O₃, (iv) from about 0.3 to about 4.1, preferably 0.7 to about 3.6 mol % Al₂O₃, (v) from about 12.3 to about 21.4, preferably 15.4 to about 20.3 mol % M₂O, wherein M is selected from the group consisting of Li, Na, K, Rb, Cs and combinations thereof, (v) from about 0.4 to about 5, preferably 0.6 to about 3.1 mol % MO, where M is selected from the group consisting of Ca, Mg, Ba, and Sr, (vi) from about 0.03 to about 5, preferably 0.05 to about 0.9 mol % Sb₂O₅, and (vii) from about 1.5 to about 10, preferably 2.1 to about 4.6 mol % F.

An embodiment of the invention is a solar cell comprising a silicon wafer and a fired contact thereon, the contact comprising, prior to firing: (a) from about 50 wt % to about 95 wt % of a conductive metal component and (b) from about 0.5 wt % to about 15 wt % of a glass component, the glass component comprising at least a first glass composition, comprising (i) from about 55 to about 80 mol % PbO, (ii) from about 4 to about 13 mol % SiO₂, (iii) from about 11 to about 22 mol % Al₂O₃, (iv) from about 3 to about 10 mol % MnO, (v) from about 0.5 to about 5 mol % M₂O₅ wherein M is selected from the group consisting of P, Ta, As, Sb, V, Nb, and combinations thereof, and (vi) from about 0.1 to about 3 mol % MO₂, wherein M is selected from the group consisting of Ti, Zr, and Hf.

An aspect of the invention is a method of making a solar cell, comprising: (a) providing a silicon wafer, (b) providing a paste composition, comprising, prior to firing, (a) from about 50 wt % to about 95 wt % of a conductive metal component, (b) from about 0.5 wt % to about 15 wt % of a glass component, the glass component comprising at least one glass composition having a glass transition temperature (Tg) less than about 600° C., (c) depositing the paste composition on at least one side of the silicon wafer, and (d) firing the wafer at a sufficient temperature for a sufficient time in order to fuse the glass component and sinter the conductive metal component.

An embodiment of the invention is a method of making a solar cell, comprising (a) providing a silicon wafer, (b) providing a paste composition, comprising, prior to firing, (i) from about 50 wt % to about 95 wt % of a conductive metal component, (ii) from about 0.5 wt % to about 15 wt % of a glass component, the glass component comprising at least one glass composition having a softening point less than about 700° C., (c) depositing the paste composition on at least one side of the silicon wafer, and (d) firing the wafer at a sufficient temperature for a sufficient time in order to fuse the glass component and sinter the conductive metal component.

An embodiment of the invention is a method of making a solar cell, comprising: (a) providing a silicon wafer, (b) providing a paste composition, comprising, prior to firing, (i) from about 50 wt % to about 95 wt % of a conductive metal component, (ii) from about 0.5 wt % to about 15 wt % of a glass component, the glass component comprising at least a first glass composition, comprising (1) from about 55 to about 80 mol % PbO, (2) from about 4 to about 13 mol % SiO₂, (3) from about 11 to about 22 mol % Al₂O₃, (4) from about 3 to about 10 mol % MnO, (5) from about 0.5 to about 5 mol % M₂O₅ wherein M is selected from the group consisting of P, Ta, As, Sb, V, Nb, and combinations thereof, and (6) from about 0.1 to about 3 mol % MO₂, wherein M is selected from the group consisting of Ti, Zr, and Hf, (c) depositing the paste composition on at least one side of the silicon wafer, and (d) firing the wafer at a sufficient temperature for a sufficient time in order to fuse the glass component and sinter the conductive metal component.

An aspect of the invention is a solar cell comprising a silicon wafer and a fired contact thereon, the contact comprising, prior to firing: (a) from about 50 wt % to about 95 wt % of a conductive metal component, (b) from about 0.5 wt % to about 15 wt % of a glass component, the glass component comprising at least a first glass composition, comprising (i) from about 24 to about 38 mol % PbO, (ii) from about 23 to about 37 mol % ZnO, (iii) from about 21 to about 37 mol % SiO₂, (iv) from about 5 to about 12 mol % Al₂O₃, and (v) from about 0.1 to about 3 mol % M₂O₅, wherein M is selected from the group consisting of Ta, P, V, Sb, Nb, and combinations thereof.

An embodiment of the invention is a method of making a solar cell, comprising: (a) providing a silicon wafer, (b) providing a paste composition, comprising, prior to firing, (i) from about 50 wt % to about 95 wt % of a conductive metal component, (ii) from about 0.5 wt % to about 15 wt % of a glass component, the glass component comprising at least a first glass composition, comprising, (1) from about 47 to about 75 mol % PbO+ZnO, (2) from about 24.3 to about 32.1 mol % SiO₂, (3) from about 6.2 to about 13.1 mol % Al₂O₃, and (4) from about 0.2 to about 4.1 mol % M₂O₅ wherein M is selected from the group consisting of P, Ta, V, Sb, Nb and combinations thereof, (c) depositing the paste composition on at least one side of the silicon wafer, and (d) firing the wafer at a sufficient temperature for a sufficient time in order to fuse the glass component and sinter the conductive metal component.

An embodiment of the invention is a solar cell comprising a silicon wafer and a fired contact thereon, the contact comprising, prior to firing, (a) from about 50 wt % to about 95 wt % of a conductive metal component (b) from about 0.5 wt % to about 15 wt % of a glass component, the glass component comprising at least a first glass composition, comprising (i) from about 43.2 to about 67.1 mol % SiO₂, (ii) from about 6.4 to about 17.9 mol % ZnO, (iii) from about 7.7 to about 15.9 mol % B₂O₃, (iv) from about 0.3 to about 4.1 mol % Al₂O₃, (v) from about 12.3 to about 21.4 mol % M₂O, wherein M is selected from the group consisting of Li, Na, K, Rb and Cs, (vi) from about 0.4 to about 3.7 mol % MO, where M is selected from the group consisting of Ca, Mg, Ba, and Sr, (vii) from about 0.03 to about 1.2 mol % Sb₂O₅, and (viii) from about 1.5 to about 5.9 mol % F.

An embodiment of the invention is a method of making a solar cell, comprising: (a) providing a silicon wafer, (b) providing a paste composition, comprising, prior to firing, (i) from about 50 wt % to about 95 wt % of a conductive metal component, (ii) from about 0.5 wt % to about 15 wt % of a glass component, the glass component comprising at least a first glass composition, comprising (1) from about 43.2 to about 67.1 mol % SiO₂, (2) from about 6.4 to about 17.9 mol % ZnO, (3) from about 7.7 to about 15.9 mol % B₂O₃, (4) from about 0.3 to about 4.1 mol % Al₂O₃, (5) from about 12.3 to about 21.4 mol % M₂O, wherein M is selected from the group consisting of Li, Na, K, Rb and Cs, (6) from about 0.4 to about 3.7 mol % MO, where M is selected from the group consisting of Ca, Mg, Ba, and Sr, (7) from about 0.03 to about 1.2 mol % Sb₂O₅, and (8) from about 1.5 to about 5.9 mol % F, (c) depositing the paste composition on at least one side of the silicon wafer, and (d) firing the wafer at a sufficient temperature for a sufficient time in order to fuse the glass component and sinter the conductive metal component.

Another embodiment of the invention is a solar cell comprising a silicon wafer and a fired contact thereon, the contact comprising, prior to firing: (a) from about 50 wt % to about 95 wt % of a conductive metal component (b) from about 0.5 wt % to about 15 wt % of a glass component, the glass component comprising at least a first glass composition, comprising (1) from about 4 to about 17 mol % ZnO, (2) from about 45 to about 64 mol % SiO₂, (3) from about 7 to about 17 mol % B₂O₃, (iv) from about 0.4 to about 3.9 mol % Al₂O₃, (v) from about 0.6 to about 3.2 mol % MO, wherein M is selected from the group consisting of Ca, Mg, Sr, Ba, and combinations thereof, (vi) from about 0.03 to about 0.95 mol % Sb₂O₅ and (vii) from about 1.5 to about 5.7 mol % F.

Still another embodiment of the invention is a method of making a solar cell, comprising: (a) providing a silicon wafer, (b) providing a paste composition, comprising, prior to firing, (i) from about 50 wt % to about 95 wt % of a conductive metal component (ii) from about 0.5 wt % to about 15 wt % of a glass component, the glass component comprising at least a first glass composition, comprising (1) from about 4 to about 17 mol % ZnO, (2) from about 45 to about 64 mol % SiO₂, (3) from about 7 to about 17 mol % B₂O₃, (4) from about 0.4 to about 3.9 mol % Al₂O₃, (5) from about 0.6 to about 3.2 mol % MO, wherein M is selected from the group consisting of Ca, Mg, Sr, Ba, and combinations thereof, (6) from about 0.03 to about 0.95 mol % Sb₂O₅ and (7) from about 1.5 to about 5.7 mol % F, (c) depositing the paste composition on at least one side of the silicon wafer, and (d) firing the wafer at a sufficient temperature for a sufficient time in order to fuse the glass component and sinter the conductive metal component.

An aspect of the invention is a paste composition comprising: a conductive metal component at about 50 wt % or more and about 95 wt % or less of the paste composition; a glass component at about 0.5 wt % or more and about 15 wt % or less of the paste composition, the glass component comprising SiO₂ at about 3 mole % or more and about 65 mole % or less of the glass component and one or more transition metal oxides at about 0.1 mole % or more and about 25 mole % or less of the glass component, the metal of the transition metal oxide is selected from the group consisting of Mn, Fe, Co, Ni, Cu, Ti, V, Cr, W, Nb, Ta, Hf, Mo, Zr, Rh, Ru, Pd, and Pt; and a vehicle at about 5 wt % or more and about 20 wt % or less of the paste composition.

In accordance with one aspect, a paste composition is provided. More particularly, in accordance with this aspect, the paste composition includes a conductive metal component, a glass component, and a vehicle. The glass component can include SiO₂ at about 3 mole % or more and about 65 mole % or less of the glass component and one or more transition metal oxides at about 0.1 mole % or more and about 25 mole % or less of the glass component. The metal of the transition metal oxide is selected from the group consisting of Mn, Fe, Co, Ni, Cu, Ti, V, Cr, W, Nb, Ta, Hf, Mo, Zr, Rh, Ru, Pd, and Pt.

In accordance with another aspect, a solar cell is provided. More particularly, in accordance with this aspect, the solar cell includes a silicon wafer and a contact thereon. The contact includes, prior to firing: a conductive metal component, a glass component, and a vehicle. The glass component can include SiO₂ at about 3 mole % or more and about 65 mole % or less of the glass component and one or more transition metal oxides at about 0.1 mole % or more and about 25 mole % or less of the glass component. The metal of the transition metal oxide is selected from the group consisting of Mn, Fe, Co, Ni, Cu, Ti, V, Cr, W, Nb, Ta, Hf, Mo, Zr, Rh, Ru, Pd, and Pt.

In accordance with yet another aspect, a method of making a paste composition is provided. More particularly, in accordance with this aspect, the method involves combining a conductive metal component, a glass component, and a vehicle, and dispersing the conductive metal component and the glass component in the vehicle. The glass component can include SiO₂ at about 3 mole % or more and about 65 mole % or less of the glass component and one or more transition metal oxides at about 0.1 mole % or more and about 25 mole % or less of the glass component. The metal of the transition metal oxide is selected from the group consisting of Mn, Fe, Co, Ni, Cu, Ti, V, Cr, W, Nb, Ta, Hf, Mo, Zr, Rh, Ru, Pd, and Pt.

In accordance with still yet another aspect, a method of forming a solar cell contact is provided. More particularly, in accordance with this aspect, the method involves providing a silicon substrate, applying a paste composition on a front side of the substrate, and heating the paste to sinter the conductive metal component and fuse the glass. The paste includes a conductive metal component, a glass component, and a vehicle. The glass component can include SiO₂ at about 3 mole % or more and about 65 mole % or less of the glass component and one or more transition metal oxides at about 0.1 mole % or more and about 25 mole % or less of the glass component. The metal of the transition metal oxide is selected from the group consisting of Mn, Fe, Co, Ni, Cu, Ti, V, Cr, W, Nb, Ta, Hf, Mo, Zr, Rh, Ru, Pd, and Pt.

To the accomplishment of the foregoing and related ends, the invention, then, involves the features hereinafter fully described and particularly pointed out in the claims. The following description and the annexed drawings set forth in detail certain illustrative embodiments of the invention. These embodiments are indicative, however, of but a few of the various ways in which the principles of the invention can be employed. Other objects, advantages and novel features of the invention will become apparent from the following detailed description of the invention when considered in conjunction with the drawings.

### BRIEF DESCRIPTION OF THE DRAWINGS

FIGS. 1-5 provide a process flow diagram schematically illustrating the fabrication of a semiconductor device. Reference numerals shown in FIGS. 1-5 are explained below.

100: p-type silicon substrate
200: n-type diffusion layer
300: front side passivation layer/anti-reflective coating (e.g., SiN_{X}, TiO₂, SiO₂ film)
400: subject paste formed on front side
402: silver or silver/aluminum back paste formed on backside
404: aluminum paste formed on backside
500: subject front electrode after firing
502: p+ layer (back surface field, BSF)
504: silver or silver/aluminum back electrode (obtained by firing silver or silver/aluminum back paste)
506: aluminum back electrode (obtained by firing aluminum back paste)

### DETAILED DESCRIPTION

The subject invention provides paste compositions including a conductive metal component, a glass component, and a vehicle. The glass component includes one or more oxides of transition metal selected from the group consisting of Mn, Fe, Co, Ni, Cu, Ti, V, Cr, W, Nb, Ta, Hf, Mo, Zr, Rh, Ru, Pd, and Pt. The paste compositions can be used to form contacts in solar cells as well as other related components. The contacts can be formed by applying the paste composition on a silicon substrate and heating the paste to sinter the conductive metal and fuse the glass frit.

Since glass is the main phase that initiates the reaction to silicon, sintering of conductive metal, e.g., silver, and development of electrical contact, any increase in its temperature and any increase in its local temperature will make these reactions to go faster and earlier in the extremely fast solar cell firing profile. Adding IR absorbing oxides and pigments as additives to the paste may increase the local wafer temperature. When these oxides are added to conventional pastes, although may improve the electrical properties, repeatability will be poor due to non uniform conduction of the heat from these particles to the glass. In the subject invention, to improve the effectiveness of transfer IR absorbing transition metal oxides are incorporated in a silica glass component of a paste. It is believed this helps to improve the electrical properties repeatably and reliably.

Thus, the paste compositions can provide one or more of the following advantages of the resulting solar cells: 1) low contact resistance, 2) high Voc, 3) high fill factor, 4) high cell efficiency, e.g., about 16.5% or more for 70 ohms/square wafers, and 5) broad firing window, e.g., about 50° C. or more of firing window. While not wishing to be bound by theory, it is believed that the incorporation of IR absorbing transition metal oxides into glass frit improves local firing temperature. This can give rise to more uniform sintering and reactivity of the paste composition with the silicon leading to lower contact resistance.

In one embodiment, the paste compositions can be used to make front contacts for silicon-based solar cells to collect current generated by exposure to light. In another embodiment, the paste compositions can be used to make back contacts for silicon-based solar cells. While the paste is generally applied by screen-printing, methods such as extrusion, pad printing, stencil printing, ink jet printing, hot melt printing or any suitable micro-deposition/direct writing techniques that one of ordinary skill in the art would recognize may also be used. Solar cells with screen-printed front contacts are fired to relatively low temperatures (550° C. to 850° C. wafer temperature; furnace set temperatures of 650° C. to 1000° C.) to form a low resistance contact between the N-side of a phosphorus doped silicon wafer and a paste. Methods for making solar cells are also envisioned herein.

In yet another embodiment, the pastes herein are used to form conductors in applications other than solar cells, and employing other substrates, such as, for example, glass, ceramics, enamels, alumina, and metal core substrates. For example, the paste is used in devices including MCS heaters, LED lighting, thick film hybrids, fuel cell systems, automotive electronics, and automotive windshield busbars.

The pastes can be prepared either by mixing individual components (i.e., metals, glass frits, and vehicles). Broadly construed, the inventive pastes include a conductive metal including at least silver, a glass including transition metal oxides, and a vehicle. Each ingredient is detailed hereinbelow.

Conductive Metal Component

The conductive metal component can contain any suitable conductive metal in any suitable form. Examples of conductive metals include silver and nickel. The source of the silver in the conductive metal component can be one or more fine particles or powders of silver metal, or alloys of silver. A portion of the silver can be added as silver oxide (Ag₂O) or as silver salts such as AgNO₃, AgOOCCH₃ (silver acetate), Ag acrylate or Ag methacrylate. Specific examples of silver particles include spherical silver powder Ag3000-1, de-agglomerated silver powder SFCGED, silver flake SF-23, nano silver powder Ag 7000-35, and colloidal silver RDAGCOLB, all commercially available from Ferro Corporation, Cleveland, Ohio.

The source of the nickel in the conductive metal component can be one or more fine particles or powders of nickel metal, or alloys of nickel. A portion of the nickel can be added as organo-nickel. Specific organo-nickel examples are nickel acetylacetonate, and nickel HEX-CEM from OMG. Other organometallic compounds based on at least one of the following metals are also contemplated for use at rates disclosed elsewhere herein for organometallic compounds: zinc, vanadium, manganese, cobalt, nickel, and iron.

All metals herein can be provided in one or more of several physical and chemical forms. Broadly, metal powders, flakes, salts, oxides, glasses, colloids, and organometallics are suitable. The conductive metal component can have any suitable form. The particles of the conductive metal component can be spherical, flaked, colloidal, amorphous, irregular shaped, or combinations thereof. In one embodiment, the conductive metal component can be coated with various materials such as phosphorus. Alternately, the conductive metal component can be coated on glass. Silver oxide can be dissolved in glass during a glass melting/manufacturing process.

In one embodiment, the metal component includes other conductive metals such as copper, nickel, palladium, platinum, gold, and combinations thereof. Further alloys such as Ag—Pd, Pt—Au, Ag—Pt, can also be used.

The conductive metal component can have any suitable size. Generally, the sizes (D50) of the conductive metal component are about 0.01 to about 20 microns, preferably about 0.05 to about 10 microns. In one embodiment, the sizes of silver and/or nickel particles are generally about 0.05 to about 10 microns, preferably, about 0.05 to about 5 microns, more preferably, about 0.05 to 3 microns. In another embodiment, the other metal particles are about 0.01 to about 20 microns, more preferably about 0.05 to about 10 microns.

In another embodiment the particles have a surface area of about 0.01 to 10 m²/g. In another embodiment, the particles have a specific surface area of about 0.1 to 8 m²/g. In another embodiment, the particles have a specific surface area of about 0.2 to 6 m²/g. In another embodiment the particles have a specific surface area of about 0.2 to 5.5 m²/g. In another embodiment the particle size distribution of the mixture of different types of silver powders in the paste (either irregular, spherical, flake, submicron or nano) can be a mono distribution or other type of distribution, for example a bi-modal or tri-modal distribution.

In one embodiment, the metal components can be provided in the form of ionic salts, such as carbonates, hydroxides, phosphates, and nitrates, of the metal of interest. Organometallic compounds of any of the metals can be used, including acetates, acrylate, methacrylate, formates, carboxylates, phthalates, isophthalates, terephthalates, fumarates, salicylates, tartrates, gluconates, or chelates such as those with ethylenediamine or ethylenediamine tetraacetic acid (EDTA). Other appropriate powders, salts, oxides, glasses, colloids, and organometallics containing at least one of the metals will be readily apparent to those skilled in the art. Generally, silver and/or other metals are provided as metal powders or flakes.

In one embodiment, the metal component include about 75 to about 100 wt % irregular shape or spherical metal particles or alternatively about 1 to about 100 wt % metal particles and about 1 to about 100 wt % metal flakes. In another embodiment, the metal component includes about 75 to about 99 wt % metal flakes or particles and about 1 to about 25 wt % of colloidal metal. The foregoing combinations of particles, flakes, and colloidal forms of the foregoing metals are not intended to be limiting, where one skilled in the art would know that other combinations are possible.

The paste composition can include any of the aforementioned conductive metal components. In one embodiment, the conductive metal component contains metal particles at about 75 wt % or more and about 100 wt % or less of the conductive metal component and metal flakes up to about 25 wt % or less of the conductive metal component. In another embodiment, the conductive metal component contains metal flakes at about 75 wt % or more and about 99 wt % or less of the conductive metal component and colloidal metal at about 1 wt % or more and about 25 wt % or less of the conductive metal component. In another embodiment, the conductive metal component contains metal particles at about 75 wt % or more and about 99 wt % or less of the conductive metal component and colloidal metal at about 1 wt % or more and about 25 wt % or less of the conductive metal component. In another embodiment, the conductive metal component contains metal particles at about 75 wt % or more and about 99 wt or less of the conductive metal component, metal flake at about 0.1 wt % or more to about 25 wt % or less of the conductive metal component and colloidal metal at about 1 wt % or more and about 10 wt % or less of the conductive metal component. The paste composition generally contains conductive metal components at any suitable amount so long as the paste can provide electrical conductivity. In one embodiment, the paste composition contains the conductive metal components at about 50 wt % or more and about 95 wt % or less of the paste composition. In another embodiment, the paste composition contains the conductive metal components at about 70 wt % or more and about 92 wt % or less of the paste composition. In yet another embodiment, the paste composition contains the conductive metal components at about 75 wt % or more and about 90 wt % or less of the paste composition.

Paste Glasses

The glass component can contain, prior to firing, silica glasses including transition metal oxides. In one embodiment, the glass component contains SiO₂ at about 3 mole % or more and about 65 mole % or less of the glass component. In another embodiment, the glass component contains SiO₂ at about 5 mole % or more and about 40 mole % or less of the glass component. In yet another embodiment, the glass component contains SiO₂ at about 3 mole % or more and about 32 mole % or less of the glass component. In still yet another embodiment, the glass component contains SiO₂ at about 3 mole % or more and about 20 mole % or less of the glass component. In another embodiment, the glass component contains SiO₂ at about 3 mole % or more and about 15 mole % or less of the glass component. In yet another embodiment the glass component contains SiO₂ at about 3 mole % or more and about 10 mole % or less of the glass component.

The glass component contains one or more transition metal oxides wherein the metal of the transition metal oxide is selected from the group consisting of Mn, Fe, Co, Ni, Cu, Ti, V, Cr, W, Nb, Ta, Hf, Mo, Zr, Rh, Ru, Pd, and Pt. The glass component contains the transition metal oxides at any suitable amount so long as the resulting contact has low resistance. In one embodiment, the glass component contains the transition metal oxides at about 0.01 mole % or more and about 25 mole % or less of the glass component. In another embodiment, the glass component contains the transition metal oxides at about 0.5 mole % or more and about 20 mole % or less of the glass component. In yet another embodiment, the glass component contains the transition metal oxides at about 0.5 mole % or more and about 15 mole % or less of the glass component. In still yet another embodiment, the glass component contains the transition metal oxides at about 0.5 mole % or more and about 10 mole % or less of the glass component.

In one embodiment, the glass component contains only one transition metal oxide, wherein the metal of the transition metal oxide is selected from the group consisting of Mn, Fe, Co, Ni, Cu, Ti, V, Cr, W, Nb, Ta, Hf, Mo, Zr, Rh, Ru, Pd, and Pt. In another embodiment, the glass component contains only two transition metal oxides, wherein the metals of the two transition metal oxides are selected from the group consisting of Mn, Fe, Co, Ni, Cu, Ti, V, Cr, W, Nb, Ta, Hf, Mo, Zr, Rh, Ru, Pd, and Pt. In another embodiment, the glass component contains three or more oxides of transition metal selected from the group consisting of Mn, Fe, Co, Ni, Cu, Ti, V, Cr, W, Nb, Ta, Hf, Mo, Zr, Rh, Ru, Pd, and Pt. In one embodiment, the glass component contains only transition metal oxides having metal selected from the group consisting of Mn, Fe, Co, Ni, Cu, Ti, V, Cr, W, Nb, Ta, Hf, Mo, Zr, Rh, Ru, Pd, and Pt, as transition metal oxides, and does not contain any other transition metal oxides. In another embodiment, the glass component contains, as transition metal oxides, only ZnO and the oxides of transition metal selected from the group consisting of Mn, Fe, Co, Ni, Cu, Ti, V, Cr, W, Nb, Ta, Hf, Mo, Zr, Rh, Ru, Pd, and Pt.

Table 1 below shows some exemplary combinations of transition metal oxides. The oxide constituent amounts for an embodiment need not be limited to those in a single column such as 1-1 to 1-12. Oxide ranges from different columns in the same table can be combined so long as the sum of those ranges can add up to 0.1-25 mole %, 0.5-20 mole %, 0.5-15 mole %, or 0.5-10 mole % of the glass component. Throughout the specification and claims, in all cases, for all tables and for all embodiments, when a range bounded by zero is indicated, this provides support for the same range bounded by 0.01 or 0.1 at the lower end.

The glass compositions herein typically are provided as frits or powders having D₅₀ particle sizes in the range of from about 0.1 to about 25 microns, preferably from about 0.1 to about 10 microns, more preferably from about 0.1 to about 4 microns, still more preferably from about 0.1 to about 2.5 microns, even more preferably from about 0.1 to about 1.2 microns, yet more preferably from about 0.1 to about 1.0 microns, still more preferably from about 0.1 to about 0.5 microns, and most preferably about 0.3 to about 1.0 microns. When more than one glass composition is used, they have D₅₀ particle sizes which may or may not be in the same range.

The glass compositions used herein have a particular glass transition temperature (Tg). For example, the Tg may fall in ranges which are more successively preferable: (a) less than about 600° C., (b) from about 250 to about 600° C., (c) from about 300 to about 600° C., (d) from about 400 to about 600° C., (e) from about 400-500° C. When more than one glass composition is used, they have Tg values which may or may not be in the same range.

The glass compositions used herein have a particular softening point. For example the softening point may fall in ranges which are successively more preferable: (a) less than about 700° C., (b) from about 350 to about 600° C., (c) from about 375 to about 600° C., (d) from about 375 to about 550° C. When more than one glass composition is used, they have softening point values which may or may not be in the same range.

TABLE 1
Transition metal oxides in mole percent of glass component.

| Oxide (mole %) | 1-1 | 1-2 | 1-3 | 1-4 | 1-5 | 1-6 | 1-7 | 1-8 | 1-9 | 1-10 | 1-11 | 1-12 |
|---|---|---|---|---|---|---|---|---|---|---|---|---|
| Mn Oxide | 0.1-25 | 0.5-20 | 1-10 | 2-8 | 4-8 | 1-4 | | | | | | |
| Fe Oxide | 0.1-25 | 0.5-20 | | | | | | 1-4 | 2-8 | 4-8 | 1-10 | |
| Co Oxide | 0.1-25 | 0.5-20 | | | | 1-10 | 2-8 | 4-8 | 1-4 | | | |
| Ni Oxide | 0.1-25 | 0.5-20 | | 1-4 | | | 2-8 | 4-8 | | 1-10 | | |
| Cu Oxide | 0.5-25 | 0.5-20 | | | | | | 1-4 | 4-8 | 2-8 | 1-10 | |
| Ti Oxide | | | | 0.1-20 | | 0.1-5 | 0.1-10 | 0.1-5 | | | | |
| V Oxide | | | | | | | | | 1-4 | 4-8 | 2-8 | 1-10 |
| Cr Oxide | | | | | | 0.1-10 | 0.1-5 | | 0.1-20 | | 0.1-5 | |
| W Oxide | | | | | | | 0.1-10 | 0.1-5 | | 0.1-20 | | 0.1-5 |
| Nb Oxide | 0.1-10 | 0.1-5 | | 0.1-20 | | 0.1-5 | | | | | | |
| Ta Oxide | 0.1-20 | 0.1-10 | 0.1-5 | | 0.1-3 | | | | | | | |
| Hf Oxide | | | | | | | | 0.1-10 | 0.1-5 | | 0.1-20 | |
| Mo Oxide | 0.1-10 | 0.1-5 | | 0.1-20 | | | 0.1-10 | 0.1-5 | | | 2-8 | 1-10 |
| Zr Oxide | | | | 0.1-20 | | 0.1-5 | | 0.1-5 | 0.1-10 | | | |
| Rh Oxide | 0.1-3 | | | | | 0.1-10 | 0.1-5 | | 0.1-20 | | 0.1-5 | |
| Ru Oxide | | 0.1-3 | | | | | | | | | | |
| Pd Oxide | | | | | | | | 0.1-3 | | 0.1-10 | | |
| Pt Oxide | | | | | | | 0.1-3 | | | | 0.1-10 | |

In one embodiment, the glass composition includes only one or more of MnO, MnO₂, Mn₂O₃, Mn₂O₄, Mn₂O₇, MnO₃, NiO, FeO, Fe₂O₃, Fe₃O₄, Cu₂O, CuO, CoO, Co₂O₃, Co₃O₄, V₂O₅, and Cr₂O₃, as transition metal oxides. For example, the glass composition includes only one or more of MnO, MnO₂, Mn₂O₃, Mn₂O₄, Mn₂O₇, MnO₃, NiO, FeO, Fe₂O₃, Fe₃O₄, Cu₂O, CuO, CoO, Co₂O₃, Co₃O₄, V₂O₅, and Cr₂O₃, wherein the contents of the transition metal oxides are about 0.5 mole % or more and about 25 mole or less of the glass component, respectively. In another embodiment, the glass composition includes only one or more of MnO, MnO₂, Mn₂O₃, Mn₂O₄, Mn₂O₇, MnO₃, NiO, FeO, Fe₂O₃, Fe₃O₄, Cu₂O, CuO, CoO, Co₂O₃, Co₃O₄, V₂O₅, and Cr₂O₃, wherein the contents of the transition metal oxides are about 0.1 mole % or more and about 25 mole % or less of the glass component, respectively. In yet another embodiment, the glass composition includes only one or more of MnO, MnO₂, Mn₂O₃, Mn₂O₄, Mn₂O₇, MnO₃, NiO, FeO, Fe₂O₃, Fe₃O₄, Cu₂O, CuO, CoO, Co₂O₃, Co₃O₄, V₂O₅, and Cr₂O₃, wherein the contents of the transition metal oxides are about 0.5 mole % or more and about 20 mole or less of the glass component, respectively. In still yet another embodiment, the glass composition includes only one or more of MnO, MnO₂, Mn₂O₃, Mn₂O₄, Mn₂O₇, MnO₃, NiO, FeO, Fe₂O₃, Fe₃O₄, Cu₂O, CuO, CoO, Co₂O₃, Co₃O₄, V₂O₅, and Cr₂O₃, wherein the contents of the transition metal oxides are about 0.5 mole % or more and about 10 mole % or less of the glass component, respectively. In addition to these transition metal oxides the glasses can contain other oxides melted in as shown in Tables 2 to 7.

In addition to the transition metal oxides containing glasses, the glass component can contain one or more of other suitable glass frits. As an initial matter, the glass frits used in the pastes herein can intentionally contain lead and/or cadmium, or they can be devoid of intentionally added lead and/or cadmium. In one embodiment, the glass frit is a substantially to completely lead-free and cadmium-free glass frit. The glasses can be partially crystallizing or non-crystallizing. In one embodiment partially crystallizing glasses are preferred. The details of the composition and manufacture of the glass frits can be found in, for example, commonly-assigned U.S. Patent Application Publication Nos. 2006/0289055 and 2007/0215202, which are hereby incorporated by reference.

More than one glass composition can be used, and exemplary glasses are shown in Tables 2-7 below. Compositions from different columns in the same table are also envisioned. Regardless of the number of glass compositions used, the contents of SiO₂ and oxides of transition metal selected from the group consisting of Mn, Fe, Co, Ni, Cu, Ti, V, Cr, W, Nb, Ta, Hf, Mo, Zr, Rh, Ru, Pd, and Pt fall within the ranges as described above.

In one embodiment, the glass component includes, prior to firing, Bi—Zn—B glasses. Table 2 below shows some exemplary Bi—Zn—B glasses. The oxide constituent amounts for an embodiment need not be limited to those in a single column such as 2-1 to 2-5.

TABLE 2
Bi—Zn—B glasses in mole percent of glass component.

| Oxide (mole %) | 2-1 | 2-2 | 2-3 | 2-4 | 2-5 |
|---|---|---|---|---|---|
| Bi₂O₃ | 25-65 | 30-60 | 32-55 | 35-50 | 37-45 |
| ZnO | 3-60 | 10-50 | 15-45 | 20-40 | 30-40 |
| B₂O₃ | 4-65 | 7-60 | 10-50 | 15-40 | 18-35 |

In another embodiment, the glass component includes, prior to firing, Bi—B—Si glasses. Table 3 below shows some exemplary Bi—B—Si glasses. The oxide constituent amounts for an embodiment need not be limited to those in a single column such as 3-1 to 3-5.

TABLE 3
Bi—B—Si glasses in mole percent of glass component.

| Oxide (mole %) | 3-1 | 3-2 | 3-3 | 3-4 | 3-5 |
|---|---|---|---|---|---|
| Bi₂O₃ | 25-65 | 30-60 | 32-55 | 35-50 | 37-45 |
| B₂O₃ | 4-65 | 7-60 | 10-50 | 15-40 | 18-35 |
| SiO₂ | 5-35 | 5-30 | 5-25 | 5-20 | 5-15 |

In yet another embodiment, the glass component includes, prior to firing, Zn glasses. Table 4 below shows some exemplary Zn glasses, both Zn—B, and Zn—B—Si glasses. The oxide constituent amounts for an embodiment need not be limited to those in a single column such as 4-1 to 4-8.

TABLE 4
Zn glasses in mole percent of glass component.

| Oxide (mole %) | 4-1 | 4-2 | 4-3 | 4-4 | 4-5 | 4-6 |
|---|---|---|---|---|---|---|
| ZnO | 5-65 | 5-65 | 7-50 | 10-32 | 6-18 | 5-14 |
| SiO₂ | 0-65 | 10-65 | 20-60 | 22-58 | 35-58 | 41-66 |
| B₂O₃ + Al₂O₃ | 5-55 | 5-55 | 7-35 | 10-25 | 11-20 | 7.5-19.4 |
| Li₂O + Na₂O + K₂O + | 0-45 | 0-45 | 2-25 | 1-20 | 11-20 | 11-23 |
| Rb₂O + Cs₂O | | | | | | |
| MgO + CaO + BaO + SrO | 0-20 | 0-20 | 0-15 | 0-10 | 0.1-5 | 0-5 |
| TiO₂ + ZrO₂ | 0-25 | 0-25 | 0-15 | 0.5-15 | 0-10 | 0-10 |
| V₂O₅ + Ta₂O₅ + Sb₂O₅ + P₂O₅ | 0-20 | 0-15 | 0-10 | 0.05-5 | 0.05-3 | 0.01-5 |
| MnO + CuO + NiO + CoO + Fe₂O₃ | 0-15 | 0-10 | 0-10 | 1-8 | 1-7 | 0-7 |
| TeO₂ + Tl₂O + GeO₂ | 0-40 | 0-30 | 0-20 | 0-20 | 0-5 | 0-5 |
| F | 0-25 | 0-20 | 0-15 | 0-8 | 0.1-6 | 1-10 |

TABLE 4a
Additional Zn glasses in mole percent.

| Oxide (mole %) | 4-7 | 4-8 | 4-9 |
|---|---|---|---|
| ZnO | 5.2-16.1 | 6.2-12.6 | 11.2-19.8 |
| SiO₂ | 47.1-63.8 | 47.3-58.1 | 46.2-60-2 |
| B₂O₃ | 8.2-15.5 | 8.4-13.8 | 14.8-21.4 |
| Al₂O₃ | 0.4-3.9 | 1.1-2.9 | 0.1-2.3 |
| Li₂O + Na₂O + K₂O + Rb₂O + Cs₂O | 14.2-22.9 | 14.2-21.7 | 9-16 |
| MgO + CaO + BaO + SrO | 0.9-2.9 | 0-15 | 0-12 |
| TiO₂ + ZrO₂ | 0-3.8 | 0-10 | 0-7 |
| V₂O₅ + Ta₂O₅ + Sb₂O₅ + P₂O₅ | 0.05-0.87 | 0.05-1 | 0.05-0.8 |
| MnO + CuO + NiO + CoO + Fe₂O₃ | 0-5.7 | 0-20 | 0-20 |
| TeO₂ + Tl₂O + GeO₂ | 0-5 | 0-5 | 0-5 |
| F | 2.1-3.9 | 1.7-7 | 0-7 |

In still yet another embodiment, the glass component includes, prior to firing, alkali-B—Si glasses. Table 5 below shows some exemplary alkali-B—Si glasses. The oxide constituent amounts for an embodiment need not be limited to those in a single column such as 5-1 to 5-5.

TABLE 5
Alkali-B—Si glasses in mole percent of glass component.

| Ingredient (mole %) | 5-1 | 5-2 | 5-3 | 5-4 | 5-5 |
|---|---|---|---|---|---|
| Li₂O + Na₂O + | 5-55 | 15-50 | 30-40 | 15-50 | 30-40 |
| K₂O | | | | | |
| TiO₂ + ZrO₂ | 0.5-30 | 0.5-20 | 0.5-15 | 1-10 | 1-5 |
| B₂O₃ + SiO₂ | 5-75 | 25-70 | 30-52 | 25-70 | 30-52 |
| V₂O₅ + Sb₂O₅ + | 0-30 | 0.25-25 | 5-25 | 0.25-25 | 5-25 |
| P₂O₅ + Ta₂O₅ | | | | | |
| MgO + CaO + | 0-20 | 0-15 | 0-10 | 0-15 | 0-10 |
| BaO + SrO | | | | | |
| MnO + CuO + | 0-15 | 0-10 | 1-10 | 1-8 | 1-7 |
| NiO + CoO + | | | | | |
| Fe₂O₃ | | | | | |
| TeO₂ + Tl₂O + | 0-40 | 0-30 | 0.05-20 | 0-20 | 0-5 |
| GeO₂ | | | | | |
| F | 0-20 | 0-15 | 5-13 | 0-15 | 5-13 |

In another embodiment, the glass component includes, prior to firing, Bi—Si—V/Zn glasses. Table 6 below shows some exemplary Bi—Si—V/Zn glasses. The oxide constituent amounts for an embodiment need not be limited to those in a single column such as 6-1 to 6-5.

TABLE 6
Bi glasses in mole percent of glass component.

| Oxide (mole %) | 6-1 | 6-2 | 6-3 | 6-4 | 6-5 | 6-6 | 6-7 | 6-8 |
|---|---|---|---|---|---|---|---|---|
| Bi₂O₃ | 5-85 | 15-80 | 20-80 | 30-80 | 40-80 | 30-42 | 39-52 | 0-21 |
| B₂O₃ + SiO₂ | 5-35 | 5-30 | 5-25 | 5-20 | 5-15 | 27-48 | 17-24 | 41-62 |
| ZnO | 0-55 | 0-40 | 0.1-25 | 1-20 | 1-15 | 0-38 | 25-39 | 0-17 |
| V₂O₅ | 0-55 | 0.1-40 | 0.1-25 | 1-20 | 1-15 | 0-5 | 0-12 | 0-12 |
| Li₂O + Na₂O + K₂O + | 0-8 | 0-7 | 0-11 | 0-12 | 14-24 | 14-24 | 1-7 | 1-7 |
| Rb₂O + Cs₂O | | | | | | | | |
| MgO + CaO + BaO + | 0-12 | 0-9 | 0-13 | 0-5 | 0-13 | 0-9 | 0-8 | 26-49 |
| SrO | | | | | | | | |

In yet another embodiment, the glass component includes, prior to firing, Pb—Al—B—Si glasses. Table 7 below shows some exemplary Pb—Al—B—Si glasses. The oxide constituent amounts for an embodiment need not be limited to those in a single column such as 7-1 to 7-12.

TABLE 7
Pb glasses in mole percent of glass component.

| Oxide (mole %) | 7-1 | 7-2 | 7-3 | 7-4 | 7-5 | 7-6 |
|---|---|---|---|---|---|---|
| PbO | 15-75 | 25-72 | 40-70 | 50-70 | 60-70 | 55-80 |
| B₂O₃ + SiO₂ | 5-38 | 20-38 | 20-38 | 5-30 | 5-15 | 4-13 |
| Al₂O₃ | 0-25 | 0.1-23 | 1-10 | 4-19 | 15-23 | 11-22 |
| ZnO | 0-35 | 5-30 | 1-10 | 5-10 | 0-5 | 0-5 |
| TiO₂ + ZrO₂ + HfO₂ | 0-20 | 0-10 | 0.1-3 | 0.1-3 | 0.1-3 | 0.1-3 |
| V₂O₅ + Sb₂O₅ + P₂O₅ + | 0-25 | 0.05-5 | 0-5 | 0-15 | 0.1-5 | 0-5 |
| Ta₂O₅ + Nb₂O₅ | | | | | | |
| MgO + CaO + BaO + SrO | 0-20 | 0-15 | 0-10 | 0-10 | 0-8 | 0-7 |
| Li₂O + Na₂O + K₂O + Rb₂O + | 0-40 | 0-30 | 0-20 | 0-10 | 0-10 | 0-8 |
| Cs₂O | | | | | | |
| MnO + CuO + NiO + | 0-15 | 0-10 | 1-10 | 1-8 | 1-7 | 0-7 |
| CoO + Fe₂O₃ | | | | | | |
| TeO₂ + Tl₂O + GeO₂ | 0-70 | 0-50 | 0-40 | 0-30 | 0-20 | 0-10 |
| F | 0-15 | 0-10 | 0-8 | 0-8 | 0-6 | 0-6 |

TABLE 7a
Further Pb glasses.

| Oxide (mole %) | 7-7 | 7-8 | 7-9 | 7-10 | 7-11 | 7-12 |
|---|---|---|---|---|---|---|
| PbO | 57-77 | 59-71 | 24-38 | 27-36 | 25.5-37 | 28-35 |
| B₂O₃ + SiO₂ | 5-11 | 6-10 | 21-37 | 22.3-33.9 | 22-35 | 23.9-33.2 |
| Al₂O₃ | 13-20 | 14-19 | 5-12 | 6.1-10.7 | 5.7-11.3 | 6.2-10.8 |
| ZnO | 0-25 | 0-31 | 0-17 | 0-13 | 24-36 | 25.2-34.7 |
| TiO₂ + ZrO₂ + HfO₂ | 0.5-2.2 | 0.7-1.9 | 0-3 | 0-8 | 0.1-3 | 0.1-3 |
| V₂O₅ + Sb₂O₅ + P₂O₅ + | 0.8-4 | 1-3.5 | 0.1-3 | 0.3-2.5 | 0.4-2.8 | 0.6-2.5 |
| Ta₂O₅ + Nb₂O₅ | | | | | | |
| MgO + CaO + BaO + SrO | 0-7 | 0-15 | 0-10 | 0-10 | 0-8 | 0-7 |
| Li₂O + Na₂O + K₂O + Rb₂O + | 0-6 | 0-30 | 0-20 | 0-10 | 0-10 | 0-8 |
| Cs₂O | | | | | | |
| MnO + CuO + NiO + | 4-9 | 4.5-7.8 | 1-10 | 1-8 | 0-7 | 0-7 |
| CoO + Fe₂O₃ | | | | | | |
| TeO₂ + Tl₂O + GeO₂ | 0-70 | 0-50 | 0-40 | 0-30 | 0-20 | 0-10 |
| F | 0-5 | 0-10 | 0-8 | 0-8 | 0-6 | 0-6 |

TABLE 7b
Further Pb Glasses.

| Oxide (mole %) | 7-13 | 7-14 | 7-15 | 7-16 |
|---|---|---|---|---|
| PbO | 55-71 | 55-71 | 57-69 | 57-69 |
| Bi₂O₃ | 0.5-5 | 0.5-5 | 0.8-4.3 | 0.8-4.3 |
| SiO₂ | 0.1-5 | 0.1-5 | 1-4 | 1-4 |
| B₂O₃ | 17-27 | 17-27 | 18.3-24.9 | 18.3-24.9 |
| ZnO | 4-9 | 0-9 | 5.1-8.2 | 0-8.2 |
| Fe₂O₃ | 0.1-5 | 0-5 | 1-4 | 0-4 |
| MnO | 0-12 | 2-12 | 0-10.7 | 3.2-10.7 |

TABLE 7c
Further Pb Glasses.

| Oxide (mole %) | 7-11 | 7-12 | 7-13 | 7-14 |
|---|---|---|---|---|
| PbO | 1-90 | 10-70 | 20-50 | 20-40 |
| V₂O₅ | 1-90 | 10-70 | 25-65 | 45-65 |
| P₂O₅ | 5-80 | 5-80 | 5-40 | 5-25 |

It is also envisioned that glass component can contain additions of predominantly vanadate glasses, phosphate glasses, telluride glasses and germinate glasses to impart specific electrical and reactivity characteristics to the resultant contacts.

The glass frits can be formed by any suitable techniques. In one embodiment, the glass frits are formed by blending the starting materials (e.g., aforementioned oxides) and melting together at a temperature of about 800 to about 1450° C. for about 40 to 60 minutes to form a molten glass having the desired composition. Depending on the raw materials used, amount of glass being melted, and the type of furnace used these ranges will vary. The molten glass formed can then be suddenly cooled by any suitable technique including water quenching to form a frit. The frit can then be ground using, for example, milling techniques to a fine particle size, from about 0.1 to 25 microns, preferably 0.1 to about 10 microns, more preferably 0.4-3.0 microns, most preferably less than 1.3 microns. It is envisioned that the finer particle sizes such as mean particle size less than 1.2 micron and more preferably less than 1.0 micron, and most preferably less than 0.8 micron are the preferred embodiments for this invention. Alternately the mean particle size can be preferably 1 to about 10 microns, alternatively 2 to about 8 microns, and more preferably 2 to about 6 microns

It is also envisioned that the glass component can contain multiple glass frits with different mean particle sizes, each as defined elsewhere herein, and in particular in the preceding paragraph.

The glass frits can have any suitable softening temperature. In one embodiment, the glass frits have glass softening temperatures of about 650° C. or less. In another embodiment, the glass fits have glass softening temperature of about 550° C. or less. In yet another embodiment, the glass frits have glass softening temperature of about 500° C. or less. The glass softening point may be as low as 350° C.

The glass fits can have suitable glass transition temperatures. In one embodiment, the glass transition temperatures range between about 250° C. to about 600° C., preferably between about 300° C. to about 500° C., and most preferably between about 300° C. to about 475° C.

The paste composition can contain any suitable amount of the glass component. In one embodiment, the paste composition contains the glass component at about 0.5 wt % or more and about 15 wt % or less. In another embodiment, the paste composition contains the glass component at about 1 wt % or more and about 10 wt % or less. In yet another embodiment, the paste composition contains the glass component at about 2 wt % or more and about 7 wt % or less. In still yet another embodiment, the paste composition contains the glass component at about 2 wt % or more and about 6 wt % or less.

Vehicle

The pastes herein include a vehicle or carrier which is typically a solution of a resin dissolved in a solvent and, frequently, a solvent solution containing both resin and a thixotropic agent. The glass fits can be combined with the vehicle to form a printable paste composition. The vehicle can be selected on the basis of its end use application. In one embodiment, the vehicle adequately suspends the particulates and burn off completely upon firing of the paste on the substrate. Vehicles are typically organic. Examples of organic vehicles include alkyl ester alcohols, terpineols, and dialkyl glycol ethers, pine oils, vegetable oils, mineral oils, low molecular weight petroleum fractions, and the like. In another embodiment, surfactants, dispersant, defoamer, plasticizer and/or other film forming modifiers can also be included.

The amount and type of organic vehicles utilized are determined mainly by the final desired formulation viscosity, fineness of grind of the paste, and the desired wet print thickness. In one embodiment, the paste includes about 5 to about 20 wt % of the vehicle. In another embodiment, the paste includes about 7 to about 15 wt % of the vehicle. In another embodiment, the paste includes about 8 to about 10 wt % of the vehicle.

The vehicle typically includes (a) at least about 50 wt % organic solvent; (b) up to about 25 wt % of a thermoplastic resin; (c) up to about 15 wt % of a thixotropic agent; and (d) up to about 10 wt % of a wetting agent. The use of more than one solvent, resin, thixotrope, and/or wetting agent is also envisioned. Ethyl cellulose is a commonly used resin. However, resins such as ethyl hydroxyethyl cellulose, wood rosin, mixtures of ethyl cellulose and phenolic resins, polymethacrylates of lower alcohols and polyacrylate can also be used. Solvents having boiling points (1 atm) from about 130° C. to about 350° C. are suitable. Widely used solvents include terpenes such as alpha- or beta-terpineol or higher boiling alcohols such as Dowanol® (diethylene glycol monoethyl ether), or mixtures thereof with other solvents such as butyl Carbitol® (diethylene glycol monobutyl ether); dibutyl Carbitol® (diethylene glycol dibutyl ether), butyl Carbitol® acetate (diethylene glycol monobutyl ether acetate), hexylene glycol, Texanol® (2,2,4-trimethyl-1,3-pentanediol monoisobutyrate), as well as other alcohol esters, kerosene, and dibutyl phthalate.

The vehicle can contain organometallic compounds, for example those based on aluminum, boron, zinc, vanadium, or cobalt, and combinations thereof, to modify the contact. N-Diffusol® is a stabilized liquid preparation containing an n-type diffusant with a diffusion coefficient similar to that of elemental phosphorus. Various combinations of these and other solvents can be formulated to obtain the desired viscosity and volatility requirements for each application. Other dispersants, surfactants and rheology modifiers, which are commonly used in thick film paste formulations, can be included. Commercial examples of such products include those sold under any of the following trademarks: Texanol® (Eastman Chemical Company, Kingsport, Tenn.); Dowanol® and Carbitol® (Dow Chemical Co., Midland, Mich.); Triton® (Union Carbide Division of Dow Chemical Co., Midland, Mich.), Thixatrol® (Elementis Company, Hightstown N.J.), Diffusol® (Transene Co. Inc., Danvers, Mass.), and Plasticizer® (Ferro Corporation, Cleveland, Ohio).

Among commonly used organic thixotropic agents is hydrogenated castor oil and derivatives thereof. A thixotrope is not always necessary because the solvent coupled with the shear thinning inherent in any suspension can alone be suitable in this regard. Furthermore, wetting agents can be employed such as fatty acid esters, e.g., N-tallow-1,3-diaminopropane di-oleate; N-tallow trimethylene diamine diacetate; N-coco trimethylene diamine, beta diamines; N-oleyl trimethylene diamine; N-tallow trimethylene diamine; N-tallow trimethylene diamine dioleate, and combinations thereof. The vehicle can contain plasticizers, surfactants and dispersants.

Other Additives

The paste compositions can optionally contain any other additives. In one embodiment, the paste composition contains one or more oxides of transition metal selected from the group consisting of Mn, Fe, Co, Ni, Cu, Ti, V, Cr, W, Nb, Ta, Hf, Mo, Zr, Rh, Ru, Pd, and Pt. These transition metal oxides are not incorporated in the glass component. Rather, the transition metal oxides are added to the paste composition as additives separately from the glass component. In one embodiment, the paste composition contains one or more oxides of transition metal selected from the group consisting of Mn, Fe, Co, Ni, Cu, Ti, V, Cr, W, Nb, Ta, Hf, Rh, Ru, Pd, and Pt at about 0.05 wt % or more and about 10 wt % or less of the paste composition, preferably at about 0.05 wt % or more and about 8 wt % or less of the paste composition, more preferably at about 0.05 wt % or more and about 5 wt % or less of the paste composition.

Apart from the transition metal oxide additives listed above, the glass component can be a mixture of (a) glasses and crystalline additives or a mixture of (b) one or more crystalline additives so that overall glass component falls within the desired compositional range discussed before. The goal is to reduce the contact resistance and improve the solar cell electrical performance. For example, crystalline materials such as Bi₂O₃, Sb₂O₃, Sb₂O₅, In₂O₃, Ga₂O₃, SnO, MgO, ZnO, Pb₃O₄, PbO, SiO₂, ZrO₂, Al₂O₃, B₂O₃, Tl₂O, TeO₂ and GeO₂ can be added to the glass component to adjust contact properties. The foregoing oxides can be added in glassy (i.e., non-crystalline) form as well. Combinations and reaction products of the aforementioned oxides can also be suitable to design a glass component with desired characteristics. For example, low melting lead silicates, either crystalline or glassy, formed by the reaction of PbO and SiO₂ such as 4PbO.SiO₂, 3PbO.SiO₂, 2PbO.SiO₂, 3PbO.2SiO₂, and PbO.SiO₂, either singly or in mixtures can be used to formulate a glass component. Similarly low melting lead borates, either crystalline or glassy, formed by the reaction of PbO and B₂O₃ either singly or in mixtures can be used to formulate a glass component. Other reaction products of the aforementioned oxides such as, Bismuth silicates such as Bi₂O₃.SiO₂, 3Bi₂O₃.5SiO₂, bismuth borates, zinc silicates such as 2ZnO.SiO₂ and ZrO₂.SiO₂, or in terms of their mineral names such as willemite, zinc borates, and zircon, can also be used. Similarly niobates such as bismuth niobates, titanates such as bismuth titanates can be used. However, the total amounts of the above oxides will fall within the ranges specified for various embodiments disclosed elsewhere herein.

In one embodiment, the paste composition contains one or more metal acetyl acetonates wherein the metal of the metal acetyl acetonate is selected from the group consisting of V, Zn, Mn, Co, Ni, Cu, Y, Zr, Ce, Ru, Rh, and Fe. The paste composition contains one or more of such metal acetyl acetonates at about 0.01 wt % or more and about 10 wt % or less of the paste composition, preferably at about 0.05 wt % or more and about 8 wt % or less of the paste composition, more preferably at about 0.05 wt % or more and about 5 wt % or less of the paste composition.

In one embodiment, the paste composition contains one or more metal silicates wherein the metal of the metal silicate is selected from the group consisting of Zn, Mg, Li, Mn, Co, Ni, Cu, Gd, Zr, Ce, Fe, Al, and Y. The metal silicate has the formula: MₓSi_{y}O_{z+2y}, wherein X=1, 2, or 3, Y=1, 2, or 3, X/Y=1/3 to 3, Z=1/2X, X, or 2×. Metal silicate can contain one or more metals M selected from the group of: Zn, Mg, Li, Mn, Co, Ni, Cu, Gd, Zr, Ce, Fe, Al, and Y. Metal silicate can be doped with other metals.

The paste composition contains one or more of such metal silicates at about 0.01 wt % or more and about 10 wt % or less of the paste composition, preferably at about 0.05 wt % or more and about 8 wt % or less of the paste composition, more preferably at about 0.05 wt % or more and about 5 wt % or less of the paste composition. The metal silicate can have any suitable particle shape. Examples of shapes of metal silicate include spherical, needle, flake, rod, or irregular shapes.

Paste Preparation

To prepare the glass component of the paste compositions, the necessary frit or frits are ground to a fine powder using conventional techniques including milling. The glass component, the conductive metal component, and optionally additives are then combined/mixed with the vehicle to form the paste. In one embodiment, the paste can be prepared by a planetary mixer.

The viscosity of the paste can be adjusted as desired. In preparing the paste compositions, the glass component and the conductive metal component are mixed with a vehicle and dispersed with suitable equipment, such as a planetary mixer or any other type of mixer which can do a thorough mixing of the paste, to form a suspension, resulting in a composition for which the viscosity will be in the range of about 200 to about 4000 poise, preferably about 400-1500 poise, more preferably 500-1200 poise at a shear rate of 9.6 sec⁻¹ as determined on a Brookfield viscometer HBT, spindle CP-51, measured at 25° C.

Printing and Firing of the Pastes

The aforementioned paste compositions can be used in a process to make a contact (e.g., fired front contact film) or other components, for example, for solar cells. The inventive method of making a solar cell contact involves applying the paste composition on a silicon substrate (e.g., silicon wafer), and heating (e.g., drying and/or firing) the paste to sinter the conductive metal component and fuse the glass. In one embodiment, the paste composition is applied on a front surface of the silicon substrate and a front contact is made. In another embodiment, the method further involves making an Ag or Ag/Al back contact by applying an Ag or Ag/Al back contact paste on the back surface of the silicon substrate and heating the Ag or Ag/Al back contact paste. In yet another embodiment, the method further involves making an Al back contact by applying an Al back contact paste on the back surface of the silicon substrate and heating the Al back contact paste.

The pastes can be applied by any suitable techniques including screen printing, ink jet printing, stencil printing, hot melt printing, decal application, extruding, spraying, brushing, roller coating or the like. In one embodiment, screen printing is preferred. Automatic screen-printing techniques can be employed using a 200-400 mesh screen to apply the paste on the front surface of the substrate.

After application of the paste to a substrate in a desired pattern, the applied coating is then dried and fired to adhere the paste to the substrate. In one embodiment, the printed pattern is dried at about 250° C. or less, preferably at about 80° C. to 250° C. for about 0.5-20 minutes before firing.

After drying the paste, the dried paste is fired to sinter the conductive metal component and fuse the glass. The firing temperature is generally determined by the frit maturing temperature, and preferably is in a broad temperature range. In one embodiment, solar cells with screen printed paste are fired to relatively low temperatures (550° C. to 850° C. wafer temperature; furnace set temperatures of 650° C. to 1000° C.) to form a low resistance contact. In another embodiment, the furnace set temperature is about 750 to about 960° C., and the paste is fired in air. In yet another embodiment, the solar cell printed with the subject paste and one or more back contact pastes can be simultaneously fired at a suitable temperature, such as about 650-1000° C. furnace set temperature; or about 550-850° C. wafer temperature.

Nitrogen (N₂) or another inert atmosphere can be used if desired when firing. The firing is generally according to a temperature profile that will allow burnout of the organic matter at about 250° C. to about 550° C., a period of peak furnace set temperature of about 650° C. to about 1000° C., lasting as little as about 1 second, although longer firing times as high as 1, 3, or 5 minutes are possible when firing at lower temperatures. For example a six-zone firing profile can be used, with a belt speed of about 1 to about 6.4 meters (40-250 inches) per minute, preferably 5 to 6 meters/minute (about 200 to 240 inches/minute). In a preferred example, zone 1 is about 18 inches (45.7 cm) long, zone 2 is about 18 inches (45.7 cm) long, zone 3 is about 9 inches (22.9 cm) long, zone 4 is about 9 inches (22.9 cm) long, zone 5 is about 9 inches (22.9 cm) long, and zone 6 is about 9 inches (22.9 cm) long. The temperature in each successive zone is typically, though not always, higher than the previous, for example, 350-500° C. in zone 1, 400-550° C. in zone 2, 450-700° C. in zone 3, 600-750° C. in zone 4, 750-900° C. in zone 5, and 800-970° C. in zone 6. Naturally, firing arrangements having more than 3 zones are envisioned by the invention, including 4, 5, 6, 7, 8 or 9 zones or more, each with zone lengths of about 5 to about 20 inches and zone set temperatures of 200 to 1000° C.

When a antireflective coating (ARC) is formed on the silicon substrate and the paste is applied on the ARC, the ARC is believed to be oxidized and corroded by the glass during firing and Ag/Si islands are formed on reaction with the Si substrate, which are epitaxially bonded to silicon. Firing conditions are chosen to produce a sufficient density of conductive metal/Si islands on the silicon wafer at the silicon/paste interface, leading to a low resistivity contact, thereby producing a high efficiency, high-fill factor solar cell.

A typical ARC is made of a silicon compound such as silicon nitride, generically SiN_{X:H}. This layer acts as an insulator, which tends to increase the contact resistance. In one embodiment, corrosion of this ARC layer by the glass component is hence a necessary step in front contact formation. Reducing the resistance between the silicon wafer and the paste can be facilitated by the formation of epitaxial metal/silicon conductive islands at the interface. When such an epitaxial metal/silicon interface does not result, the resistance at that interface becomes unacceptably high. The pastes and processes herein can make it possible to produce an epitaxial metal/silicon interface leading to a contact having low resistance under broad processing conditions—a minimum wafer temperature as low as about 650° C., but which can be fired up to about 850° C. (wafer temperature).

The resulting fired front contact can include conductive metal at about 70 wt % or more and about 99 wt % or less of the fired front contact and a glass binder at about 1 wt % or more and about 15 wt % or less of the fired front contact. In one embodiment, the fired front contact includes conductive metal at about 70 wt % or more and about 99 wt % or less of the fired front contact, a glass binder at about 1 wt % or more and about 15 wt % or less of the fired front contact, and additives such as aforementioned transition metal oxides, metal acetyl acetonates, metal silicates, or combinations thereof at about 0.05 wt % or more and about 10 wt % or less of the fired front contact.

Method of Front Contact Production

A solar cell contact according to the invention can be produced by applying any conductive paste disclosed herein to a substrate, for example, by screen-printing to a desired wet thickness, e.g., from about 20 to about 80 microns. Automatic screen-printing techniques can be employed using a 200-400 mesh screen. The printed pattern is then dried at 250° C. or less, preferably about 80 to about 250° C. for about 0.5-20 minutes before firing. The dry printed pattern can be fired for as little as 1 second up to about 30 seconds at peak temperature, in a belt conveyor furnace in air. During firing, the glass is fused and the metal is sintered.

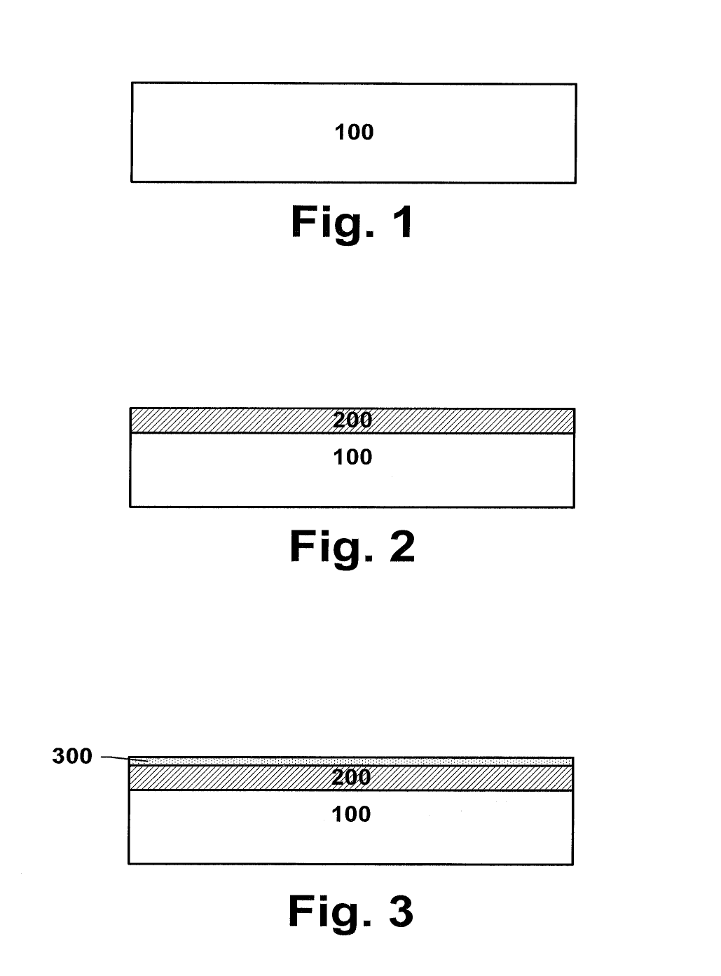

Referring now to FIGS. 1-5, one of many exemplary methods of making a solar cell front contact according to the present invention is illustrated. In this example, the method involves making a first and second back contact also.

FIG. 1 schematically shows providing a substrate 100 of single-crystal silicon or multicrystalline silicon. The substrate typically has a textured surface which reduces light reflection. In the case of solar cells, substrates are often used as sliced from ingots which have been formed from pulling or casting processes. Substrate surface damage caused by tools such as a wire saw used for slicing and contamination from the wafer slicing step are typically removed by etching away about 10 to 20 microns of the substrate surface using an aqueous alkali solution such as KOH or NaOH, or using a mixture of HF and HNO₃. The substrate optionally can be washed with a mixture of HCl and H₂O₂ to remove heavy metals such as iron that can adhere to the substrate surface. An antireflective textured surface is sometimes formed thereafter using, for example, an aqueous alkali solution such as aqueous potassium hydroxide or aqueous sodium hydroxide. This gives the substrate, 100, depicted with exaggerated thickness dimensions. The substrate is typically a p-type silicon having about 200 microns or less of thickness.

FIG. 2 schematically illustrates that, when a p-type substrate is used, an n-type layer 200 is formed to create a p-n junction. Examples of n-type layers include a phosphorus diffusion layer. The phosphorus diffusion layer can be supplied in any of a variety of suitable forms, including phosphorus oxychloride (POCl₃), and organophosphorus compounds. The phosphorus source can be selectively applied to only one side of the silicon wafer, e.g., a front side of the wafer. The depth of the diffusion layer can be varied by controlling the diffusion temperature and time, is generally about 0.2 to 0.5 microns, and has a sheet resistivity of about 40 to about 120 ohms per square. The phosphorus source can include phosphorus-containing liquid coating material. In one embodiment, phosphosilicate glass (PSG) is applied onto only one surface of the substrate by a process such as spin coating, where diffusion is effected by annealing under suitable conditions.

FIG. 3 schematically illustrates forming an antireflective coating (ARC) 300, which also usually serves as a passivation layer also on the above-described n-type diffusion layer 200. The ARC layer typically includes SiN_{X}, TiO₂, or SiO₂. Silicon nitride is sometimes expressed as SiN_{X:H} to emphasize passivation by hydrogen. The ARC 300 reduces the surface reflectance of the solar cell to incident light, thus increasing the amount of light absorption, and thereby increasing the electrical current generated. The thickness of passivation layer 300 depends on the refractive index of the material applied, although a thickness of about 700 to 900 Å is desired to give suitable refractive index

The passivation layer 300 can be formed by a variety of procedures including low-pressure CVD, plasma CVD, or thermal CVD. When thermal CVD is used to form a SiN_{X} coating, the starting materials are often dichlorosilane (SiCl₂H₂) and ammonia (NH₃) gas, and film formation is carried out at a temperature of at least 700° C. When thermal CVD is used, pyrolysis of the starting gases at the high temperature results in the presence of substantially no hydrogen in the silicon nitride film, giving a substantially stoichiometric compositional ratio between the silicon and the nitrogen, i.e., Si₃N₄.

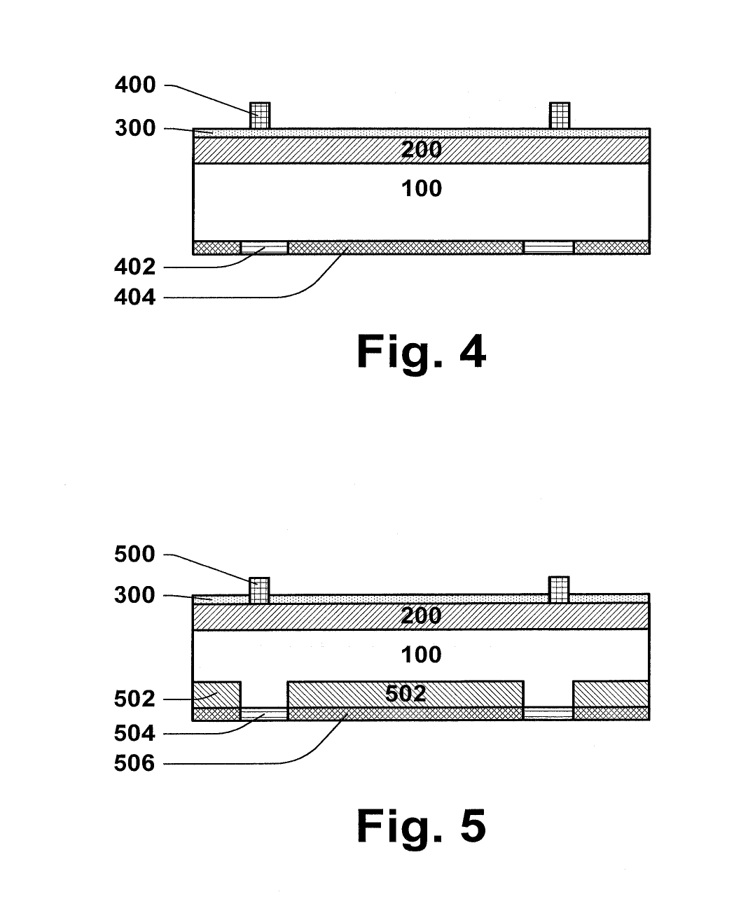

FIG. 4 schematically illustrates applying the subject paste composition 400 over the ARC film 300. The paste composition can be applied by any suitable technique. For example, the paste composition can be applied by screen print on the front side of the substrate 100. The pastes can be applied selectively by screen printing to a suitable wet thickness, for example, about 20 to 80 microns and successively dried on the front side of the substrate. The paste composition 400 is dried at about 125° C. for about 10 minutes. Other drying times and temperatures are possible so long as the paste vehicle is dried of solvent, but not combusted or removed at this stage. While not individually labeled, it is noted that FIG. 4 shows two segments of paste 400 applied to the front side of the silicon wafer 100. The front side of silicon wafer 100 can have any suitable number of segments of the paste 400. Although not shown individually in FIG. 4, the bus bars and fingers of paste 400 run perpendicular to each other on top surface.

FIG. 4 further illustrates forming a layer of back side pastes over the back side of the substrate 100. The back side paste layer can contain one or more paste compositions. In one embodiment, a first paste 402 facilitates forming a back side contact and a second paste 404 facilitates forming a p+ layer over the back side of the substrate. The first paste 402 can contain silver or silver-aluminum mixture and the second paste 404 can contain aluminum. An exemplary backside silver paste is Ferro PS 33-610, Ferro PS 33-612, or Ferro PS2131, silver-aluminum paste is Ferro 3398, commercially available from Ferro Corporation, Cleveland, Ohio. An exemplary commercially available backside aluminum paste is Ferro AL53-120, AL53-112, AL860, or AL5116, commercially available from Ferro Corporation, Cleveland, Ohio.

The back side paste layer can be applied to the substrate and dried in the same manner as the front paste layer 400. In this embodiment, the back side is largely covered with the aluminum paste, to a wet thickness of about 30 to 50 microns, owing in part to the need to form a thicker p+ layer in the subsequent process.

FIG. 5 schematically illustrates forming front contacts 500. The front contact paste 400 is transformed by firing from a dried state 400 to a front contact 500. The front contact paste 400 sinters and penetrates through (i.e., fires through) the ARC layer 300 during firing, and is thereby able to electrically contact the n-type layer 200 on the silicon substrate 100.

The first back paste (rear contact paste) 402 can be fired at the same time, becoming an Ag or Ag/Al back contact 504. The second back paste 404 can be fired at the same time, becoming an Al back contact 506. The areas of the back side paste 504 can be used for tab attachment during module fabrication.

FIG. 5 further schematically illustrates forming a Back Surface Field (BSF) layer 502. Aluminum of the paste 404 melts and reacts with the silicon substrate 100 during firing, then solidifies forming a partial p+ layer, 502, containing a relatively higher concentration of aluminum dopant. This layer is generally called the back surface field (BSF) layer, and helps to improve the energy conversion efficiency of the solar cell.

A solar cell front contact according to the present invention can be produced by applying any paste composition disclosed herein, produced by mixing metal components, with the glass component of Tables 1-8, to the n-side of the silicon substrate, for example by screen printing, to a desired wet thickness, e.g., from about 20 to 50 microns.

### EXAMPLES

The following examples illustrate the subject invention. Unless otherwise indicated in the following examples and elsewhere in the specification and claims, all parts and percentages are by weight, all temperatures are in degrees Celsius, and pressure is at or near atmospheric pressure.

Exemplary paste compositions formulated and tested are shown in Table 8. With respect to Chemistry I of Table 8, NS178 paste the glass component contains no transition metal oxides that could color the glasses. Paste A includes the same components as NS178, except that the glass component of Paste A includes glasses containing MnO. Paste B includes the same components as NS178, except that the glass component of Paste B includes glasses containing NiO.

With respect to Chemistry II of Table 8, a glass component of NS188 paste contains no transition metal oxides that could color the glasses. Paste C though K includes the same components as NS188, except that the glass component of Paste C and D further includes glasses containing NiO, Paste E and F further includes glasses containing CuO, paste G and H further includes glasses containing CoO, paste I and J further includes glasses containing MnO, paste K further includes glasses containing Fe₂O₃.

The pastes of Table 8 are applied on a SiNx front layer (i.e., front passivation layer) having a thickness of about 70-90 nm on a silicon wafer to form a paste layer having a fired thickness of 5-50 microns. Polycrystalline silicon wafers, used in the following examples were 243 cm² in area, about 180 microns thick, and had a sheet resistivity of 65-95 ohms per square. The pastes are printed on the front passivated side of the wafer, dried and fired. The pastes are fired in a six-zone infrared belt furnace with a belt speed of about 5.08 meters per minute (200 inch per minute), with temperature settings of 400° C., 400° C., 500° C., for first three zones, and 700° C., 800° C. and 920° C. in last three zones, respectively. The lengths of the zones of the six-zone infrared belt furnace are 45.7, 45.7, 22.9, 22.9, 22.9, and 22.9 cm long, respectively. The details of paste preparation, printing, drying and firing can be found in commonly owned U.S. Patent Application Publication Nos. US2006/0102228 and US 2006/0289055, the disclosures of which are incorporated by reference. Series resistances (Rs) of the resulting contacts are measured. Relative values of series resistances compared to the control pastes NS178 in Chemistry I and NS188 in Chemistry II, respectively are shown in Table 8.

TABLE 8
Front paste composition and relative series resistances.

| | | | mole % | |
|---|---|---|---|---|
| | | Transition | transition | Rs |
| | | metal oxide in | metal oxide | (Rela- |
| Chemistry | Paste | glass component | in the glass | tive) |
| I | NS178 (ref I) | — | — | 1.00 |
| | A | MnO | 5.3 | 0.97 |
| | B | NiO | 5.8 | 1.23 |
| II | NS188 (ref II) | — | — | 1.00 |
| | C | NiO | 5.8 | 0.81 |
| | D | NiO | 10.9 | 0.90 |
| | E | CuO | 5.5 | 1.07 |
| | F | CuO | 10.3 | 0.86 |
| | G | CoO | 2.7 | 0.89 |
| | H | CoO | 5.2 | 0.87 |
| | I | MnO | 5.3 | 0.92 |
| | J | MnO | 9.5 | 0.95 |
| | K | Fe₂O₃ | 2.8 | 0.81 |

The results in Table 8 show that the inventive pastes have lower series resistances compared to the reference pastes without any transition metal oxides in the glass component.

Further exemplary paste compositions formulated and tested are shown in Table 9. In Chemistry III, different two glass systems containing transition metal oxides are compared to paste A of Table 8 (the optimized candidate from earlier investigation) while keeping the D₅₀ particle size of glass powders at about 3 microns. Paste A includes 71-93 mol % glass 7-6 and 7-29 mol % of a glass including from about 17 to about 51 mol % PbO, from about 14 to about 47 mol % ZnO, from about 24.3 to about 32.1 mol % SiO₂, from about 6.2 to about 13.1 mol % Al₂O₃, and from about 0.2 to about 4.1 mol % M₂O₅ wherein M is selected from the group consisting of P, Ta, V, As, Sb, Nb and combinations thereof.

Pastes L and M include each includes 81-94 mol % of glass 7-6 in Table 7 and 6-19 mol % of glass 7-13 in Table 7. Paste N includes 71-83 mol % of glass 7-6 and 17-29 mol % of glass 4-9 in Table 4. Paste P includes 71-83 mol % of glass 7-6 and 17-29 mol % of glass 4-6. Paste R includes 81-94 mol % of glass 7-6 and 6-19 mol % of glass 6-6.

Paste S includes 71-93 mol % of glass 7-6, 7-13 mol % of a glass including from about 17 to about 51 mol % PbO, from about 14 to about 47 mol % ZnO, from about 24.3 to about 32.1 mol % SiO₂, from about 6.2 to about 13.1 mol % Al₂O₃, and from about 0.2 to about 4.1 mol % M₂O₅ wherein M is selected from the group consisting of P, Ta, V, As, Sb, Nb and combinations thereof and 6-12 mol % of glass glass 7-13. Paste U includes 59-72 mol % of glass 7-6, 7-14 mol % of a glass including from about 17 to about 51 mol % PbO, from about 14 to about 47 mol % ZnO, from about 24.3 to about 32.1 mol % SiO₂, from about 6.2 to about 13.1 mol % Al₂O₃, and from about 0.2 to about 4.1 mol % M₂O₅ wherein M is selected from the group consisting of P, Ta, V, As, Sb, Nb and combinations thereof and 15-23 mol % of glass 4-6.

Paste V includes 71-93 mol % of glass 7-6, 7-14 mol % of a glass including from about 17 to about 51 mol % PbO, from about 14 to about 47 mol % ZnO, from about 24.3 to about 32.1 mol % SiO₂, from about 6.2 to about 13.1 mol % Al₂O₃, and from about 0.2 to about 4.1 mol % M₂O₅ wherein M is selected from the group consisting of P, Ta, V, As, Sb, Nb and combinations thereof and 4-10 mol % of glass 6-7.

Pastes W and X include 71-93 mol % of glass 7-6 and 7-14 mol % of a glass including from about 17 to about 51 mol % PbO, from about 14 to about 47 mol % ZnO, from about 24.3 to about 32.1 mol % SiO₂, from about 6.2 to about 13.1 mol % Al₂O₃, and from about 0.2 to about 4.1 mol % M₂O₅ wherein M is selected from the group consisting of P, Ta, V, As, Sb, Nb and combinations thereof. Paste X1 includes 61-73 mol % of glass 7-6, 7-15 mol % of glass 7-1, and 27-39 mol % of glass 4-6. Paste Y includes 71-93 mol % of glass 7-6 and 7-29 mol % glass 4-6. Paste Z includes 53-64 mol % glass 7-6 and 36-47 mol % glass 4-6.

This comparison shows that further reduction in Rs is possible by varying MnO as well as MnO+Fe2O3 contents in different base glass chemistries. In Table 9, Chemistry IV list relative Rs values obtained for three glass powders compared to that of paste A of Table 8 as reference. This clearly shows reduction in Rs is more prevalent with three glass powders in the glass component.

In Table 9 Chemistry V compares the effect of finer glass powders (D 50=0.7 to 1.0 microns) instead of regular glass powders (D50=3.0 microns) in the references. The two sets of comparisons in chemistry V shows that finer glass powders lower Rs. For Chemistry V, the Rs values for pastes W and X were determined at 80 Ohm, while Rs values for pastes Y and Z were determined at 95 Ohm.

TABLE 9
Front paste composition and relative series resistances.

| | | Transition | mole % | Rs |
|---|---|---|---|---|
| | | metal oxide in | transition | (Rela- |
| Chemistry | paste | glass component | metal oxides | tive) |
| III | A | MnO | 5.3 | 1 |
| 2 glass | (Reference III) | | | |
| system, 3.0 | L | MnO + Fe₂O₃ | 5.72 | 0.899 |
| micron | M | MnO + Fe₂O₃ | 6.41 | 0.949 |
| glass D50 | N | MnO | 4.82 | 0.953 |
| Different | P | MnO | 4.74 | 0.984 |
| glass | R | MnO | 5.6 | 0.904 |
| chemistries | | | | |
| IV | S | MnO + Fe₂O₃ | 5.04 | 0.876 |
| Three glass | T | MnO | 5.71 | 0.862 |
| systems, | U | MnO | 4.18 | 0.933 |
| 3.0 micron | V | MnO | 4.97 | 0.883 |
| glass D50 | | | | |
| Different | | | | |
| glass | | | | |
| chemistries | | | | |
| V | A | MnO | 5.3 | 1.000 |
| Effect of | (Reference V) | | | |
| glass | W | MnO | 5.3 | 0.967 |
| particle | X | MnO | 5.31 | 0.896 |
| size- | U | MnO | 4.17 | 1.000 |
| Normal | (Reference VI) | | | |
| (D50 = 3 | Y | MnO | 4.63 | 0.787 |
| micron) vs | Z | MnO | 3.56 | 0.773 |
| finer (D50 = | | | | |
| 0.7-1.0 | | | | |
| micron) | | | | |

What has been described above includes examples of the subject invention. It is, of course, not possible to describe every conceivable combination of components or methodologies for purposes of describing the subject invention, but one of ordinary skill in the art may recognize that many further combinations and permutations of the subject invention are possible. Accordingly, the subject invention is intended to embrace all such alterations, modifications and variations that fall within the spirit and scope of the appended claims. Furthermore, the foregoing ranges (e.g., compositional ranges and conditional ranges) are preferred and it is not the intention to be limited to these ranges where one of ordinary skill in the art would recognize that these ranges may vary depending upon specific applications, specific components and conditions for processing and forming the end products. One range can be combined with another range. To the extent that the terms “contain,’ “have,” “include,” and “involve” are used in either the detailed description or the claims, such terms are intended to be inclusive in a manner similar to the term “comprising” as “comprising” is interpreted when employed as a transitional word in a claim. In some instances, however, to the extent that the terms “contain,’ “have,” “include,” and “involve” are used in either the detailed description or the claims, such terms are intended to be partially or entirely exclusive in a manner similar to the terms “consisting of” or “consisting essentially of” as “consisting of or “consisting essentially of” are interpreted when employed as a transitional word in a claim.

1. A paste composition comprising:
a. from about 50 wt % to about 95 wt % of a conductive metal component;
b. from about 0.5 wt % to about 15 wt ° A of a glass component,
the glass component comprising at least one glass composition having a glass transition temperature (T_{g}) of less than about 600° C.

2. The paste composition of claim 1, wherein the T_{g} of the at least one glass composition is from about 250 to about 600° C., more preferably from about 300 to about 600° C., more preferably from about 400 to about 600° C., and most preferably from about 400 to about 500° C.

3-5. (canceled)

6. The paste composition of claim 1, wherein the glass component comprises at least one of a first glass composition, second glass composition, third glass composition, or combination thereof, each glass composition having a T_{g} in a range of less than about 600° C., preferably from about 250 to about 600° C., more preferably from about 300 to about 600° C., more preferably from about 400 to about 600° C., and most preferably from about 400-500° C., wherein the first glass composition, second glass compositions, and third glass composition are not the same.

7. (canceled)

8. The paste composition of claim 1, wherein
b. from about 0.5 wt % to about 15 wt % of a glass the at least one glass composition has softening point of less than about 700° C.

9. The paste composition of claim 8, wherein the softening point of the at least one glass composition is from about 350 to about 650° C., preferably from about 350 to about 600° C., more preferably from about 375 to about 600° C., and most preferably from about 375 to about 550° C.

10-12. (canceled)

13. The paste composition of claim 6, wherein the second glass composition and the third glass composition each have a softening point in a range of less than about 700° C., preferably from about 350 to about 600° C., more preferably from about 375 to about 600° C., and most preferably from about 375 to about 550° C., wherein the first glass composition, second glass composition, and third glass composition are not the same.

14-15. (canceled)

16. The paste composition of claim 6, wherein the first glass composition comprises particles having a D₅₀ size of about 0.1 to about 10 microns, preferably about 0.1 to about 4 microns, more preferably about 0.1 to about 2.5 microns, more preferably about 0.1 to about 1.2 microns, more preferably about 0.1 to about 1.0 microns, more preferably about 0.1 to about 0.5 microns, and most preferably about 0.3 to about 1.0 microns.

17-22. (canceled)

23. composition of claim 6, wherein the second glass composition, third glass composition, or both comprises particles having a D₅₀ size in a range of from about 0.1 to about 10 microns, more preferably from about 0.1 to about 4 microns, more preferably from about 0.1 to about 2.5 microns, more preferably from about 0.1 to about 1.2 microns, more preferably from about 0.1 to about 1.0 microns, more preferably from about 0.1 to about 0.5 microns, and most preferably from about 0.3 to about 1.0 microns, wherein the first glass composition and second glass composition are not the same.

24. (canceled)

25. The paste composition of claim 1, wherein the glass component comprises a first glass composition, comprising:
i. from about 55 to about 80 mol % PbO,
ii. from about 4 to about 13 mol % SiO₂,
iii. from about 11 to about 22 mol % Al₂O₃,
iv. from about 3 to about 10 mol % MnO,
v. from about 0.5 to about 5 mol % M₂O₅, wherein M is selected from the group consisting of P, Ta, As, Sb, V, Nb, and combinations thereof, and
vi. from about 0.1 to about 3 mol % M0₂, wherein M is selected from the group consisting of Ti, Zr, and Hf.

26-27. (canceled)

28. The paste composition of claim 25, wherein the glass component further comprises a second glass composition, comprising:
a. from about 24 to about 38 mol % PbO,
b. from about 23 to about 37 mol % ZnO,
c. from about 21 to about 37 mol % SiO₂,
d. from about 5 to about 12 mol % Al₂O₃, and
e. from about 0.1 to about 3 mol % M₂O₅, wherein M is selected from the group consisting of Ta, P, V, Sb, Nb, and combinations thereof.

29. (canceled)

30. The paste composition of claim 25, wherein the glass component further comprises a second glass composition, comprising:
a. from about 5 to about 14 mol % ZnO,
b. from about 41 to about 66 mol % SiO₂,
c. from about 7 to about 15.2 mol % B₂O₃,
d. from about 0.5 to about 4.2 mol % Al₂O₃,
e. from about 11 to about 23 mol % M₂O, wherein M is selected from the group consisting of Li, Na, K, Rb, Cs, and combinations thereof,
f. from about 0.01 to about 5 mol % Sb₂O₅ and
g. from about 1 to about 10 mol % F.

31-41. (canceled)

42. The paste composition of claim 1, wherein the conductive metal component comprises particles having a D₅o size of about 0.01 to about 20 microns, preferably about 0.05 to about 10 microns, and more preferably about 0.05 to 3 microns.

43. The paste composition of claim 1, wherein the conductive metal particles have a surface area of about 0.01 to 10 m²/g, preferably about 0.1 to 8 m²/g, more preferably about 0.2 to 6 m 2/g, still more preferably about 0.2 to 5.5 m 2/g.

44. A solar cell comprising a silicon wafer and a contact thereon, the contact comprising, prior to firing:
a. from about 50 wt % to about 95 wt % of a conductive metal component,
b. from about 0.5 wt % to about 15 wt of a glass component, the glass component comprising at least a first glass composition having a glass transition temperature (T_{g}) of less than about 600° C.

45. A method of making a solar cell, comprising:
a. providing a silicon wafer having at least one side;
b. providing a paste composition, comprising, prior to firing,
i. from about 50 wt % to about 95 wt % of a conductive metal component,
ii. from about 0.5 wt % to about 15 wt % of a glass component, the glass component comprising at least one glass composition having a glass transition temperature (T_{g}) of less than about 600° C.;
c. depositing the paste composition on the at least one side of the silicon wafer; and
d. firing the wafer at a sufficient temperature for a sufficient time in order to fuse the glass component and sinter the conductive metal component.

46. The method of claim 45, wherein the at least one glass composition has a softening point of less than about 700° C.

47-79. (canceled)

80. The solar cell according to claim 44, wherein the first glass composition has a softening point of less than about 700° C.
